(19) United States
(12) Patent Application Publication
(10) Pub. No.: US 2015/0173238 A1
(43) Pub. Date: Jun. 18, 2015

(54) CONFIGURABLE POWER CONVERTER PACKAGE

(71) Applicant: Caterpillar Inc., Peoria, IL (US)

(72) Inventors: Todd Nakanishi, Brimfield, IL (US); Jon Husser, McNabb, IL (US); Timothy Finn, Peoria Heights, IL (US); Ray Wise, Metamora, IL (US); Marcus M. Chui, Naperville, IL (US)

(73) Assignee: Caterpillar Inc., Peoria, IL (US)

(21) Appl. No.: 14/132,311

(22) Filed: Dec. 18, 2013

(51) Int. Cl. H05K 7/20; H02M 7/00; H05K 7/02

(52) U.S. Cl. CPC H05K 7/209; H05K 7/026; H02M 7/003

(57) ABSTRACT

A configurable power converter package is disclosed. The configurable design allows for the power converter to support the drivetrain needs of a product line of machines without having to design a new power converter for each application. Major components of the power converter package such as the housing, heat sink, power modules, and bus bars are designed to be combined into a number of different power configurations. The power configurations fulfill the needs of a product line of electric drivetrains without the need to design a new power converter package for each application.

### TECHNICAL FIELD

The present disclosure relates to a configurable design of a power converter and its components. The configurable design allows for the power converter to support the drivetrain needs of a product line of machines without having to design a new power converter for each application.

### BACKGROUND

Power converters are commonly used to convert AC power from a generator to DC power, and then from DC power to AC power for use by a motor. Power conversion requires switching of large currents by power semiconductor devices, such as insulated gate bipolar transistors (IGBTs). An electric drive traction application typically includes both AC/DC conversion to receive power from a generator and DC/AC conversion to power a motor. The generator is typically driven by an engine.

Power converters are typically designed to operate within specific power ranges. Semiconductor devices and copper conductors are expensive. Excess power capability is a waste of money, material, space, and weight. Therefore, new applications in different power ranges typically require the development of new power converter designs.

The power modules are the heart of the power converter and are densely packaged with the rest of the power converter components. The power module dictates the shape and position of the AC and DC bus bars, the configuration of the gate drive boards, and the configuration of the heat sink. Switching to a different power module typically requires redesigning the adjoining components.

Most electric drivetrains for machines use induction motor/generator technology or permanent magnet (PM) motor/generator technology. In either case, the power converter architecture is the same and uses power modules optimized for this application. Such power modules have insulated gate bipolar transistors (IGBTs) and diodes packaged in a configuration that supports induction/PM applications. The power modules for induction/PM applications are configured to receive or provide power in multiple phase configurations, such as a three phase (X, Y, Z) configuration.

However, many drivetrain applications are moving to switched reluctance (SR) motor technology, which offers a simpler rotor design at the expense of more complex motor controls. SR technology also uses IGBTs and diodes, but requires a power module with a different configuration than induction/PM technology. The power modules for SR applications are not limited to a three phase output. The number of outputs is determined by the number of stator poles and rotor poles and therefore may have more than three outputs. Current power converter designs do not support the use of both induction/PM and SR applications.

Different power converter applications may also have different requirements for locations of external connections. Such connections may include DC connections, AC connections, coolant connections, control connections, and accessory connections. Power converters may be used in different locations on a machine, and each location may require different locations for the connections. For example, a power converter may be connected to a generator or a motor, each of which is located on a different part of the machine. Likewise, if the machine has two or more drive motors, a power converter may require different locations for the connections. For example, motors on the front and rear or left and right sides of the machine may require connection locations that are mirror images of the other. This would normally require a new power converter to be developed for each location, or at least force the designer to accept less than desirable packaging and cable routing on the machine.

The cost of designing a power converter is considerable. Significant engineering time is required for proper bus bar routing, board layouts, housing design, and power module design. The design cost for power modules is particularly high. Tooling is also an important consideration. For example, the tooling for a single housing design can be in excess of $100,000. Each time a new power converter is designed for a new application, new tooling is needed. Typically, a single housing design cannot be used for different power converter designs.

Accordingly, the power converter is a significant portion of an electric drivetrain cost. Production volumes are needed to drive down costs in order to make electric drivetrains feasible for more applications in a product line. Therefore it is desirable to design a power converter package that can be adapted to a large number of configurations while changing a minimum number of components. Thus, the power converter design can fulfill the needs of an entire product line of electric drivetrains thereby saving non-recurring engineering (NRE) costs and tooling costs associated with creating new designs for every application.

United States Patent Application No. 20060120001 to Weber et al., issued Jun. 8, 2006, entitled “Modular power supply assembly,” known hereafter as the Weber Reference. The Weber Reference discloses “A modular power converter that is easily adapted to a wide variety of applications . . . . ” However, The Weber Reference takes a very different approach from the current disclosure and states that “A fundamental approach of the present design is to separate the typical drive inverter and converter design functions of a power converter into separate assemblies.”

### SUMMARY OF THE INVENTION

A power converter package is disclosed. The power converter package comprises a housing configured to accept a heat sink, a filter capacitor, one of a plurality of terminal block configurations, one of a plurality of configurations of power module configured in a set and mounted to said heat sink, a DC bus bar electrically connected to said filter capacitor and said power modules, one of a plurality of configurations of AC bus bars connected to said power module and said terminal block, and wherein the power converter package forms one of a plurality of power configurations.

In a second aspect of the current disclosure, a method for assembling a power converter package is disclosed. The method for assembling a power converter package comprises providing a housing, mounting a heat sink, mounting a filter capacitor to said housing, mounting one of a plurality of terminal block configurations to said housing, mounting one of a plurality of configurations of power module to said heat sink, said configurations configured in a set, electrically connecting a DC bus bar to said filter capacitor and said power module, electrically connecting one of a plurality of configurations of AC bus bars to said power module and said terminal block, and wherein the power converter package forms one of a plurality of power configurations.

### BRIEF DESCRIPTION OF THE DRAWINGS

FIG. 1 is a perspective view of a power converter package according to the current disclosure.

FIG. 2 is a front view of a housing according to the current disclosure.

FIG. 3 is a back view of power converter configuration 240 according to the current disclosure.

FIG. 4 is a schematic of configuration 240.

FIG. 5 is a view and schematic of two power modules according to the current disclosure.

FIG. 6 is a view of a heat sink mounted to a housing according to the current disclosure.

FIG. 7 is a view of a plurality of bus bars according to the current disclosure.

FIG. 8 is a view of a plurality of terminal blocks according to the current disclosure.

FIG. 9 is a view of a plurality of gate boards according to the current disclosure

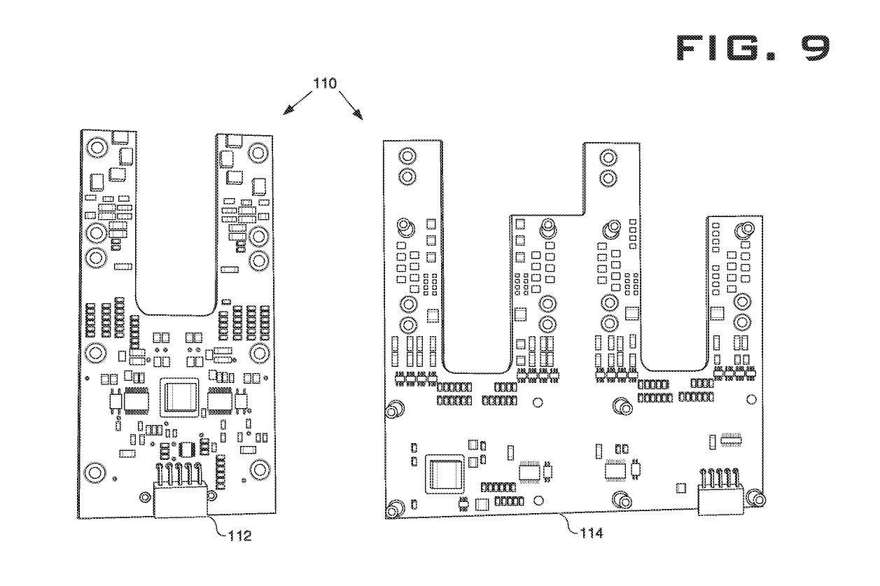

FIG. 10 is a table that illustrates a number of configurations that are fulfilled by a configurable power converter package according to the current disclosure.

FIG. 11 is a back view of power converter configuration 250 according to the current disclosure.

FIG. 12 is a schematic of configuration 250

FIG. 13 is a back view of power converter configuration 270 according to the current disclosure.

FIG. 14 is a schematic of configuration 270

FIG. 15 shows an electric drivetrain according to the current disclosure

FIG. 16 shows an electric drivetrain according to the current disclosure

FIG. 17 shows an electric drivetrain according to the current disclosure

FIG. 18 shows an electric drivetrain according to the current disclosure

FIG. 19 shows an electric drivetrain according to the current disclosure

FIG. 20 shows examples of machine configurations according to the current disclosure

FIG. 21 shows examples of machine configurations according to the current disclosure

FIG. 22 shows examples of machine configurations according to the current disclosure

### DETAILED DESCRIPTION

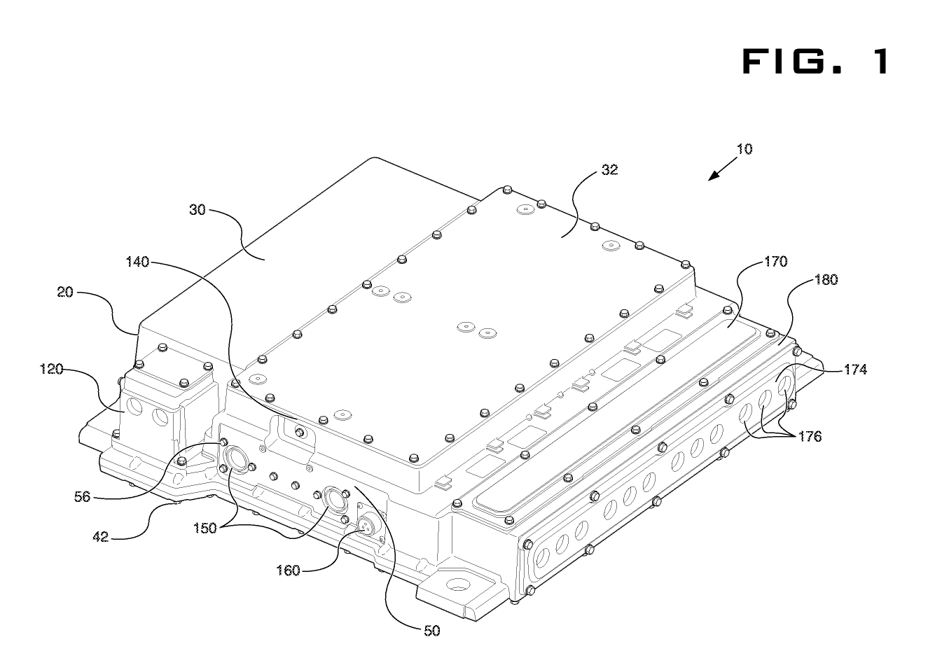

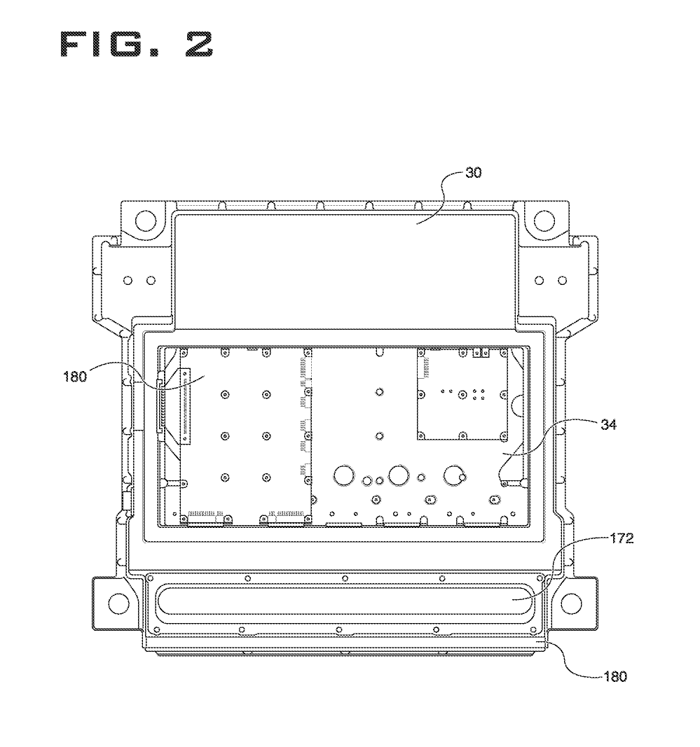

The power converter package 10 as shown in FIGS. 1-3 includes a housing 20. The housing is made of metal and is cast and/or machined. The housing has a front 30 and a front cover 32 that covers a front compartment 34. The front compartment 34 contains an interface board 200 that connects to a controller 202 through a controls connector 140. The interface board 200 provides signal processing between the controller 202 and the gate drive boards 110 and sensors, etc. in the power converter package 10. The housing 20 includes provisions to allow the controls connector 140 be mounted on either of the left or right sides. The housing 20 also includes provisions to allow a DC connection box to be mounted on either of the left or right sides.

The housing 20 also has a back 40 and a back cover 42 that covers a back compartment 44. The back compartment 44 has provisions for mounting a filter capacitor 70, a heat sink 50, an accessory connector 160. The housing 20 includes provisions to allow the accessory connector 160 mounted on either of the left or right sides.

Provisions are included in the housing 20 that allow the DC connection box 120, controls connector 140, the accessory connector 160 to be mounted on either the left or right side. For instance, mounting bosses are included on both left and right sides to allow mounting of the DC connection box 120. Finish machining, drilling, and tapping may then be performed in either location depending on where the DC connection box 120 needs to be mounted for a particular application. The application may require one, two, or no DC connection boxes 120. The provision for controls connector 140 includes a flat that can be machined and mounting bosses to allow mounting on either the left or right side. Similarly, provisions are provided for the accessory connector 160 to be mounted on either the left or right side.

The housing 20 includes an AC connection compartment 180 at one end. The AC connection compartment 180 provides access for AC power connection from outside the housing 20 to the components inside the housing 20. Connections are provided via lug-and-gland type connectors from the AC cables 190 to a terminal block 80. Access is provided by a front AC connection plate 170, a back AC connection plate 172, and a bottom AC connection plate 174. The AC connection plates are attached to the housing 20 via mounting flanges. Any of the AC connection plates can be configured with cable apertures 176 to allow AC cables 190 to pass through. In this fashion, AC cables 190 may be routed to the power converter package 10 from the front, back or bottom.

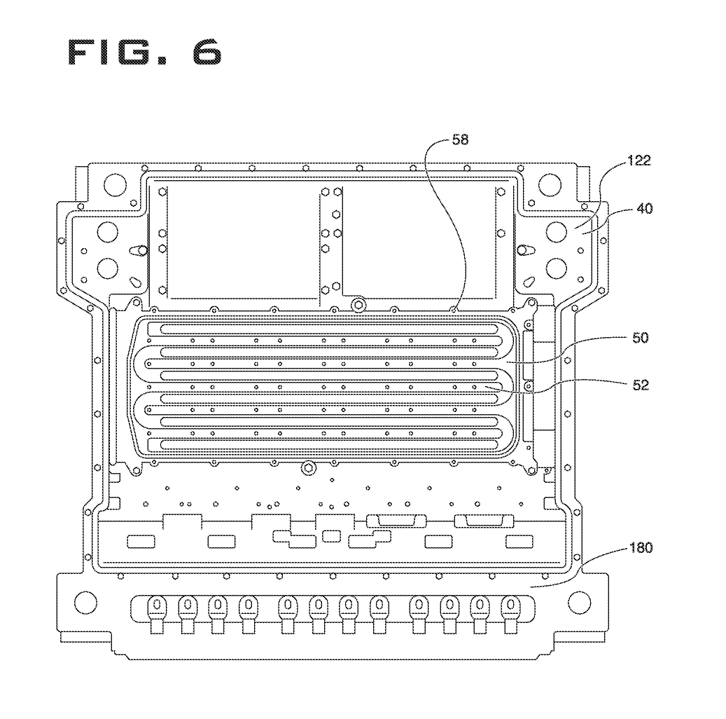

As shown in FIG. 6, the heat sink 50 bolts to the housing 20 inside the housing back compartment 44. One surface of the heat sink 50 is machined flat and includes power module mounting holes 52 for mounting a plurality of power modules 60. Coolant passages are provided that route through the heat sink 50 to remove heat generated by the power modules 60. The heat sink 50 and housing 20 are configured such that the heat sink 50 can be mounted with the coolant inlet/outlet connections 150 on either of the left or right side. The housing 20 includes a housing aperture 56 that is added to accommodate the coolant inlet/outlet connections 150. The heat sink mounting holes 54 for the bolts that attach the heat sink 50 to the housing 20 are arranged in symmetry about the left-right axis 210 allowing the heat sink 50 to be attached to the housing in either of two orientations. In this way, the power converter package 10 can provide coolant inlet/outlet connections 150 on either the left or right side while using the same housing 20 and heat sink 50. In one aspect of the current disclosure, the power module mounting holes 52 that attach the power modules 60 to the heat sink 50 are configured with a symmetry about the left-right axis 210 of the power converter package 10, allowing proper mounting of the power modules 60 in either mounting configuration. In another aspect of the current disclosure, the power module mounting holes 52 located in the heat sink 50 are symmetric about a left-right axis of the heat sink 50.

The power modules 60 typically include paired silicon-based insulated gate bipolar transistors (IGBTs) and fly-back diodes. The IGBTs are enclosed in a case and electrically connected to connection terminals. Connection terminals are also included for connection of the IGBT gates to a gate drive board 110. A backing plate is thermally connected to the IGBTs and diodes. Heat generated by the IGBTs during switching is conducted through the backing plate and into the heat sink 50 where it can be removed by circulating coolant. Mounting holes are provided through the case and backing plate for mounting the power modules 60 to the heat sink 50.

The power converter package 10 according to the present disclosure is designed to work with either induction/PM or switched reluctance (SR) technology. Induction/PM and SR technology require power modules 60 with different configurations. An induction/PM power module 62 is configured with both IGBTs in series. Three induction/PM power modules 62 in a power module set 66 are typically used to provide three-phase AC that connects to a stator winding of an induction/PM machine such as a motor or generator. An SR power module 64 is configured with both IGBTs in parallel and provides power for one stator winding of an SR machine such as a motor or generator. SR power modules 64 in a power module set 66 can be combined to provide AC power to multi-phase SR machines.

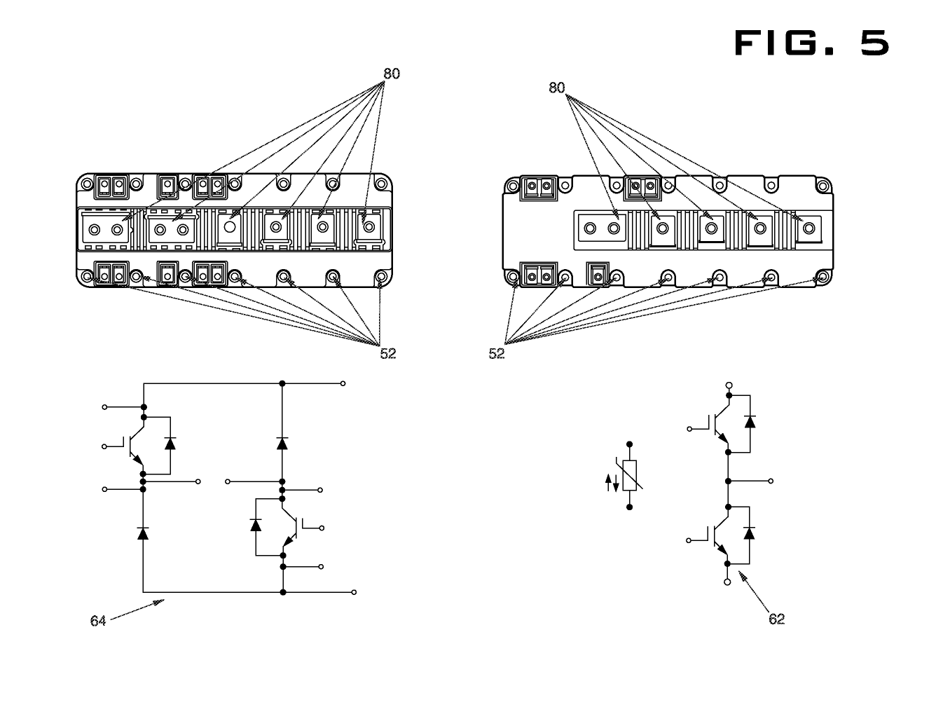

Though possible, it is inefficient from a space and cost perspective to use an induction/PM configuration to power an SR machine. As such, power converters are not typically designed to accommodate both induction/PM and SR technology. A power converter package 10 that can accommodate both induction/PM and SR technology would require a power module 60 that is available in both induction/PM and SR configurations. Such a power module 60 is shown in FIG. 5. This power module 60 is available as an induction/PM power module 62 and an SR power module 64 and is available exclusively from Infineon Industrial Power Division of Lebanon, N.J. The induction/PM power module 62 and SR power module 64 have identical mounting and DC connection configurations and are therefore mechanically interchangeable save for the start/finish or AC connections.

Filter capacitors 70 are mounted in the housing back compartment 44 and are electrically connected to the DC bus bar 90 via screw terminals. The mounting arrangement of the filter capacitors 70 is designed to accommodate high vibration environments. The filter capacitors 70 provide bulk capacitance that is needed to dampen ripple current that occurs on the DC link that connects the power converter package 10 to loads or different power conversion stages. The bulk capacitance also serves to filter out harmonic content and voltage spikes of the DC link voltage. Film capacitors are often the preferred choice for mobile applications and can be packaged and mounted in a variety of ways.

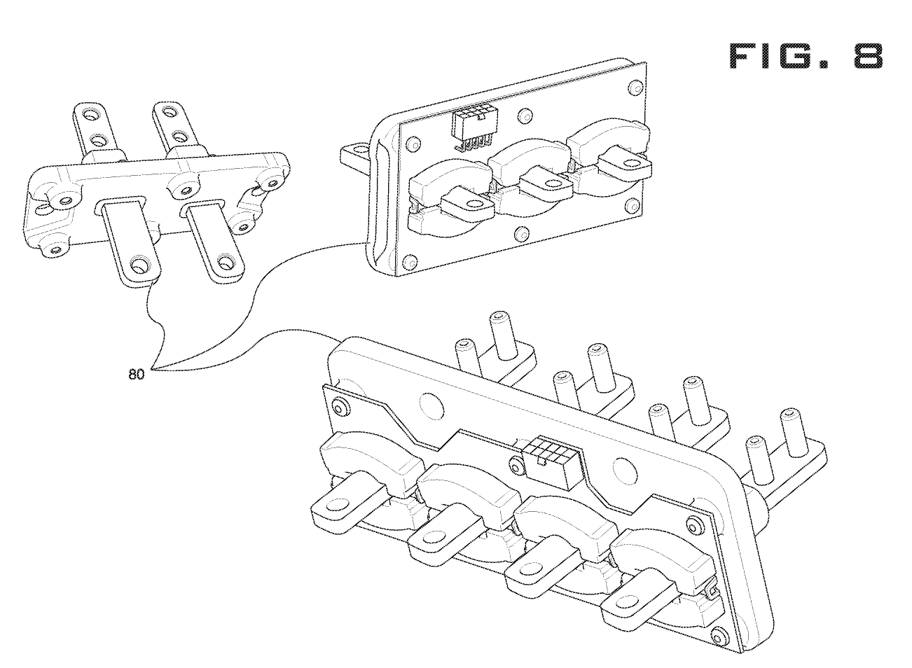

The power converter package 10 includes a terminal block 80 shown in FIG. 8 that connects the AC bus bars 100 to the AC cables 190. Connecting lugs on the terminal block 80 extend into the AC connection compartment 180 where they connected to the AC cables 190 via lug-and-gland style connections. The terminal block 80 includes a printed circuit board (PCB) with a soldered hall-effect current sensor and a plastic isolator with conductors. The pieces are assembled together as a sub-assembly and then assembled into the power converter package 10. The assembly is capable of conducting and sensing current for any number of conductors as needed for the power converter application. The combination of hall-effect sensor and conductor assembly results in a smaller and less expensive solution than the industry standard approach.

The terminal block 80 is designed in configurations with two, three, or four connector lugs. The three configurations or combinations of the three configurations of terminal blocks 80 is sufficient to meet all the required applications of the power converter package.

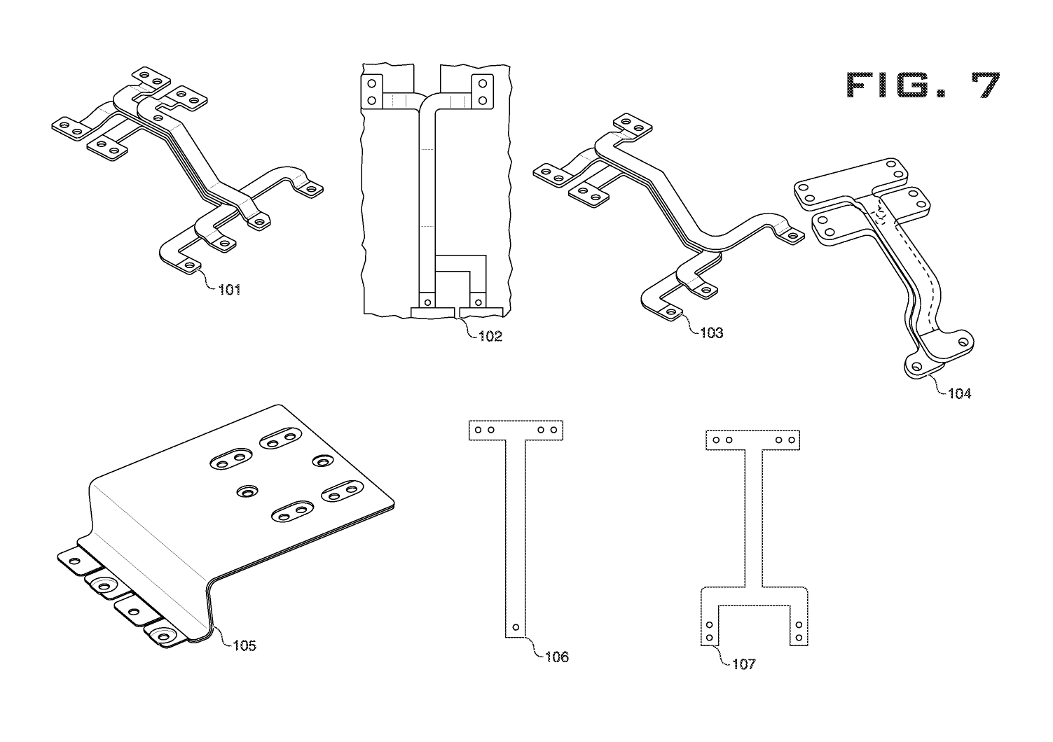

FIG. 7 shows a plurality of AC bus bars 100 for use with the power converter package 10 of the current disclosure. The AC bus bars 100 connect the power terminals of the power modules 60 to the terminal block 80. The AC bus bars 100 of the current disclosure are intended to route together in pairs between pairs of power modules 60 in order to save space, but any other routing technique is possible without departing from the intent of the current disclosure. An AC bus bar 100 is formed by laminating or adhering multiple conductors together, where the conductors are individually insulated from the other conductors.

The SR Dual Input/Four Terminal bus bar 101 includes four conductors and is designed to connect the start and finish terminals of two SR power modules 64 to the lugs of a terminal block 80. The AC Dual Input/Two Terminal bus bar 102 includes two conductors and is designed to connect the AC terminals of two induction/PM power modules 62 to the lugs of a terminal block 80. The Hybrid SR/AC Three Terminal bus bar 103 includes three conductors and is designed to connect the start and finish terminals of two SR power modules 64 and the AC terminal of an induction/PM power module 62 to the lugs of a terminal block 80. The SR Parallel Input/Two Terminal bus bar 104 includes two conductors and is designed to connect the start terminals of two SR power modules 64 and the finish terminals of two SR power modules 64 to the lugs of a terminal block 80. The SR Parallel Input/Four Terminal bus bar 105 includes two conductors and is designed to connect the start terminals of two SR power modules 64 and the finish terminals of two SR power modules 64 to the lugs of a terminal block 80. The second end of each conductor connects to two lugs. The AC Parallel Input/One Terminal bus bar 106 includes one conductor and is designed to connect the AC terminals of two induction/PM power modules 62 to the lugs of a terminal block 80. The AC Parallel Input/Two Terminal bus bar 107 includes one conductor and is designed to connect the AC terminals of two induction/PM power modules 62 to the lugs of a terminal block 80. The second end of each conductor connects to two lugs.

The relative location of the power module mounting holes 52 in the heat sink 50 may change to allow the spacing between power modules 60 to vary in order to accommodate larger conductors to be used in high power applications.

The DC bus bar 90 connects the positive and negative DC terminals of the power module 60 to the respective terminals of the filter capacitor 70. The DC bus bar 90 is formed by laminating two conductors together, where each of the conductors is individually insulated from the other conductor.

Provisions to connect to the DC bus bar 80 to an accessory connector 160 and a DC access bar 130 are provided. Said provisions can be in the form of threaded terminals, crimp lugs, or the like. The DC bus has properties of symmetry about the left-right axis 210 and has provisions to connect to the DC bus bar 80 to an accessory connector 160 and a DC access bar 130 on the left and right side.

The DC access bar 130 is a two conductor laminated bus bar that connects the DC bus bar 80 to the DC connection box 120. A first end of the DC access bar 130 can connect to the DC bus bar 80 in either of two locations. The second end of the DC access bar 130 connects to a DC terminal block that is mounted to the bottom of the DC connection box 120. The DC access bar has properties of symmetry and is designed to connect to the DC connection box 120 whether the DC connection box 120 is mounted on the left or the right side of the housing 20.

The DC connection box 120 is a connection box that can be located on either the left, right, or both sides of the housing 20. The DC connection box 120 provides access for DC power connection from outside the housing 20 to the components inside the housing 20. The DC connection box 120 includes a DC terminal block that is mounted to the housing at the base of the DC connection box and is electrically connected to the DC access bar 130. Connections are provided via lug-and-gland type connectors from the DC cables 192 to the DC terminal block. In some applications, an external DC bus bar may be used instead of DC cables 192.

The gate drive board 110 is configured to take commands from a controller 202 through the interface board 200 and generate switching commands for the power modules 60. Switching commands are given to the power modules 60 via connectors carrying control-level voltage signals. The gate drive board 110 of the current disclosure is designed in two configurations. The first configuration supports a single power module 60. The second configuration supports two power modules 60 that are connected in parallel. Either configuration is able to support an induction/PM power module 62 or an SR power module 64.

The power converter package 10 of the current disclosure is designed to be adapted to a large number of configurations while changing a minimum number of components. The power converter package 10 is therefore configurable to fulfill the needs of an entire product line of electric drivetrains 310 and the need to design and pay for tooling all new components for each application is avoided.

For example, the housing 20, heat sink 50, filter capacitor 70, and DC bus bar 90 are common between every power converter package 10 configuration. In addition, only one power module 60 footprint serves all power converter package 10 configurations.

Symmetry is a major theme among many components, including the housing 20, heat sink 50, power module 60, DC bus bar 90, DC connection box 120, and DC access bar 130. Symmetry in shape and mounting configuration allows such components to be mounted in different locations within the power converter package 10 or able to be combined with different versions of other components without modification.

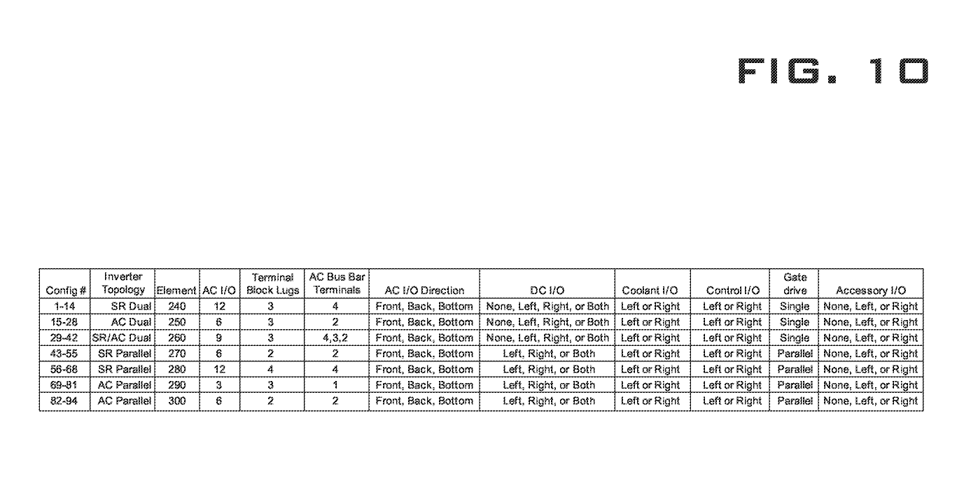

The table in FIG. 10 shows the configurations that are able to be satisfied by the power converter package 10, including the topologies, and major components. The major topologies will be briefly described below.

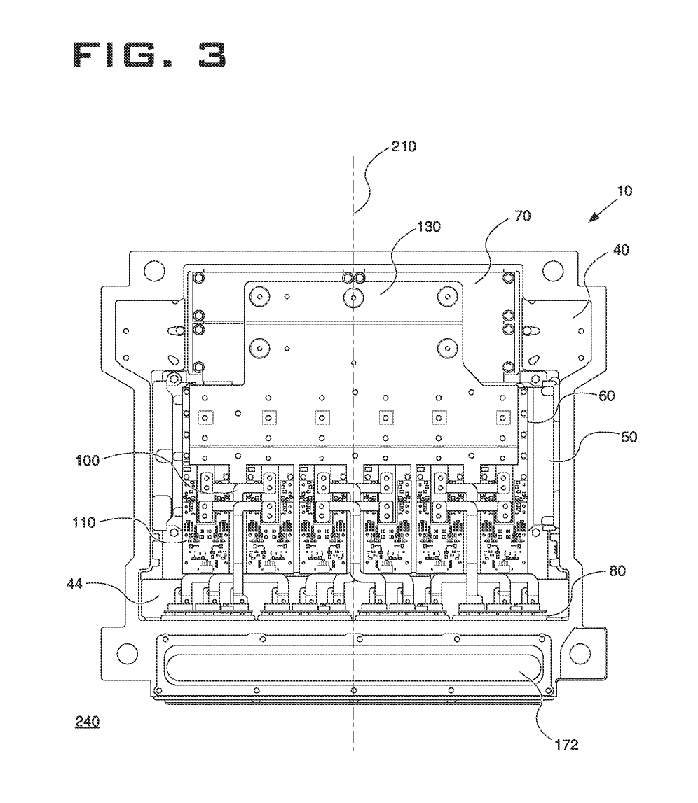

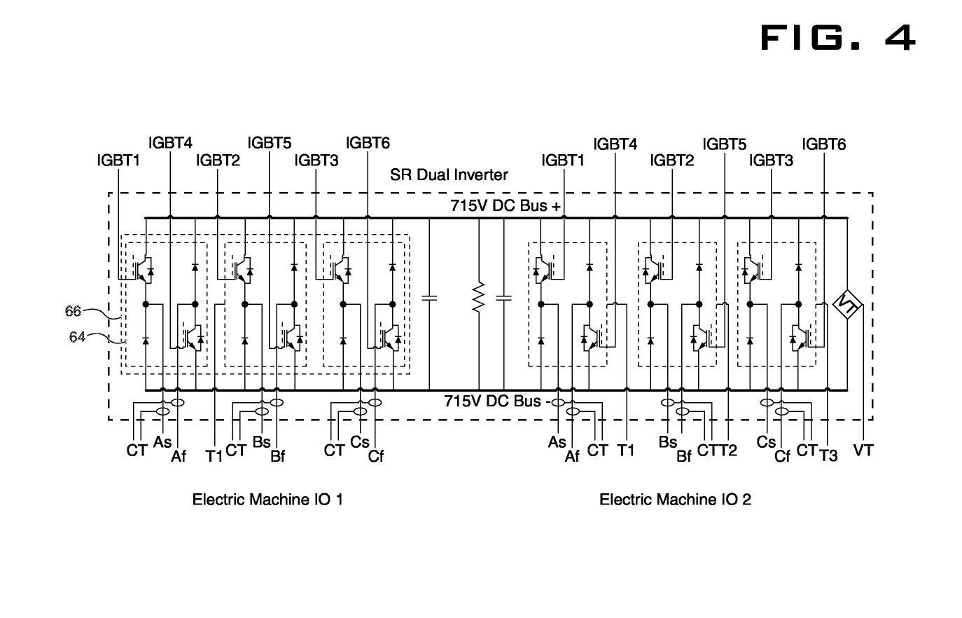

The first topology shown in FIG. 10 will be referred to as an SR Dual Topology 240. The SR Dual Topology 240 is assembled from two power module sets 66, with each set containing only SR power modules 64. The SR Dual Topology 240 of the power converter package 10 provides two power conversion stages. That is, the SR Dual Topology 240 receives AC power from an SR machine such as a generator, converts the power to DC, then converts the power to AC and provides AC power to an SR machine such as a motor. The SR Dual Topology 240 could also receive DC power and drive two SR machines. The first topology uses the single gate drive board 112. An example configuration of the SR Dual Topology 240 is shown in FIG. 3. An equivalent circuit diagram of the SR Dual Topology 240 is shown in FIG. 4.

Each AC bus bar 100 of the SR Dual Topology 240 includes four conductors that connect a terminal of an SR power module to a lug on a terminal block 80. The SR Dual Topology 240 uses terminal blocks 80 with three lugs. The AC bus bar 100 used in the SR Dual Topology 240 will be referred to as an SR Dual Input/Four Terminal bus bar 101.

For example, a first AC bus bar 100 includes a first conductor that is connected to the start terminal of a first SR power module 64 at a first end and a first lug of a first terminal block 80 at a second end. The first AC bus bar 100 further includes a second conductor that is connected to the finish terminal of the first SR power module 64 at a first end and to a second lug of the first terminal block at a second end. A third conductor is connected to the start terminal of a second SR power module 64 at a first end and a third lug of the first terminal block 80 at a second end. A fourth conductor is connected to the finish terminal of the second SR power module 64 at a first end and a first lug of a second terminal block 80 at a second end.

A second AC bus bar 100 includes a first conductor that is connected to the start terminal of a third SR power module 64 at a first end and a second lug of a second terminal block 80 at a second end. The second AC bus bar 100 further includes a second conductor that is connected to the finish terminal of the third SR power module 64 at a first end and to a third lug of the second terminal block at a second end. A third conductor is connected to the start terminal of a fourth SR power module 64 at a first end and a first lug of a third terminal block 80 at a second end. A fourth conductor is connected to the finish terminal of the fourth SR power module 64 at a first end and a second lug of a third terminal block 80 at a second end.

A third AC bus bar 100 includes a first conductor that is connected to the start terminal of a fifth SR power module 64 at a first end and a third lug of a third terminal block 80 at a second end. The third AC bus bar 100 further includes a second conductor that is connected to the finish terminal of the fifth SR power module 64 at a first end and to a first lug of a fourth terminal block at a second end. A third conductor is connected to the start terminal of a sixth SR power module 64 at a first end and a second lug of a fourth terminal block 80 at a second end. A fourth conductor is connected to the finish terminal of the sixth SR power module 64 at a first end and a third lug of a fourth terminal block 80 at a second end.

The first, second, and third AC bus bars 100 may be identical, or they may be slightly different to accommodate routing variations.

Cable apertures 176 can be provide in the front, back, or bottom AC connection plates 170, 172, 174 to allow AC cables 190 to be connected to the terminal blocks 80 from the front, back, or bottom of the power converter package 10.

Though the SR Dual Topology 240 provides two power conversion stages, it may be useful in some applications to provide a DC connection box 120 so that an energy storage device (not shown) may be connected. The energy storage device could be a battery, ultracapacitor, or the like, or possibly to another power converter. The DC connection box 120 may be absent, or it may be located on the left or right side. In some applications it may be present on both the left and right sides.

Further, the SR Dual Topology 240 may have the coolant inlet/outlet connection 150, the controls connector 140, and the accessory connector 160 located on either of the left or right sides. The accessory connector 160 may be absent in some applications.

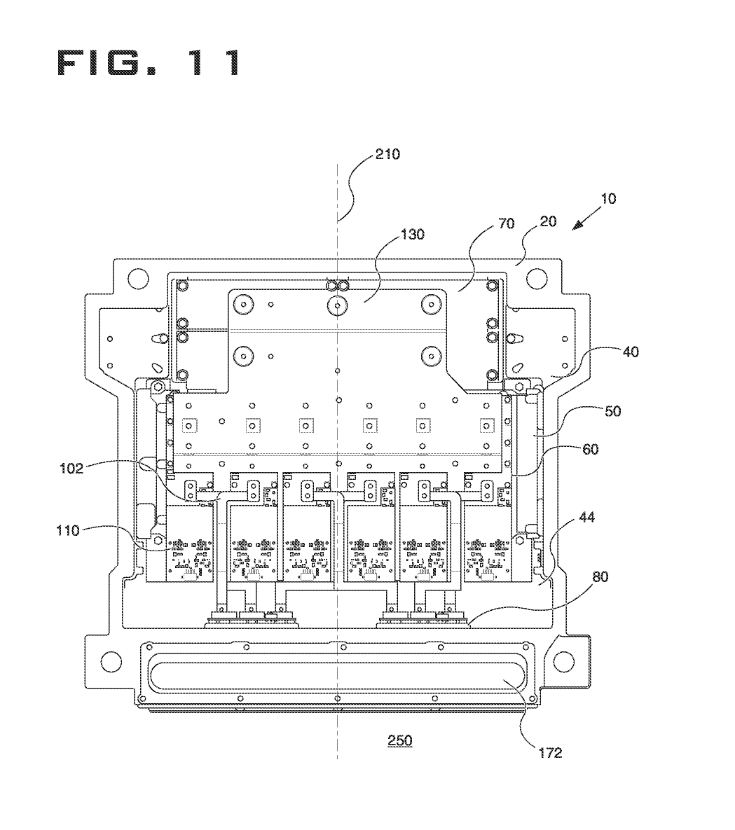

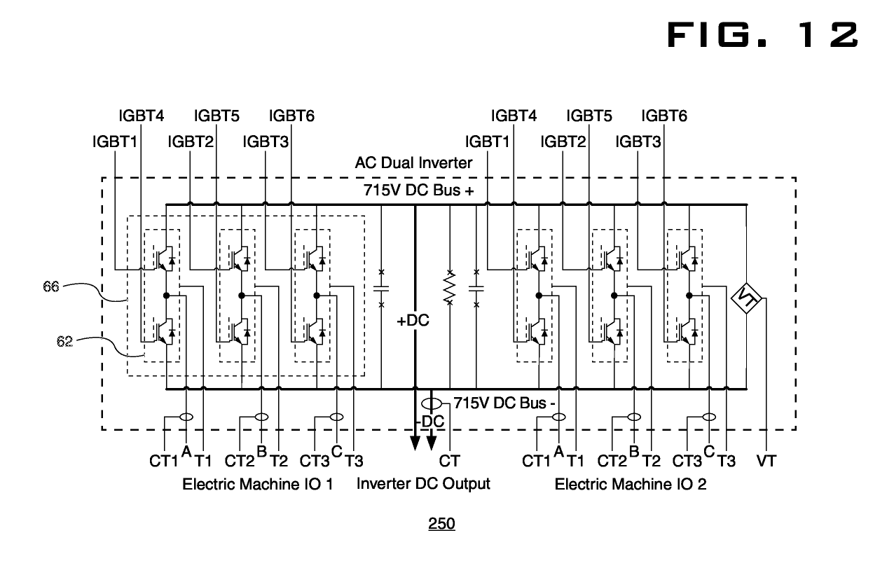

The second topology shown in FIG. 11 will be referred to as an AC Dual Topology 250. The AC Dual Topology 250 is assembled from two power module sets 66, with each set containing only induction/PM power modules 62. The AC Dual Topology 250 of the power converter package 10 provides two power conversion stages. That is, the AC Dual Topology 250 receives AC power from an induction/PM machine such as a generator, converts the power to DC, then converts the power to AC and provides AC power to an induction/PM machine such as a motor. The AC Dual Topology 250 could also receive DC power and drive two induction/PM machines. An example configuration of the AC Dual Topology 250 is shown in FIG. 11. An equivalent circuit diagram of the AC Dual Topology 250 is shown in FIG. 12.

Each AC bus bar 100 of the AC Dual Topology 250 includes two conductors that connect a terminal of an AC power module to a lug on a terminal block 80. The AC Dual Topology 250 uses terminal blocks 80 with two lugs. The AC bus bar 100 used in the AC Dual Topology 250 will be referred to as an AC Dual Input/Two Terminal bus bar 102.

For example, a first AC bus bar 100 includes a first conductor that is connected to the AC terminal of a first induction/PM power module 62 at a first end and a first lug of a first terminal block 80 at a second end. The first AC bus bar 100 further includes a second conductor that is connected to the AC terminal of a second induction/PM power module 62 at a first end and to a second lug of the first terminal block at a second end.

A second AC bus bar 100 includes a first conductor that is connected to the AC terminal of a third induction/PM power module 62 at a first end and a third lug of a first terminal block 80 at a second end. The second AC bus bar 100 further includes a second conductor that is connected to the AC terminal of a fourth induction/PM power module 62 at a first end and to a first lug of the second terminal block at a second end.

A third AC bus bar 100 includes a first conductor that is connected to the AC terminal of a fourth induction/PM power module 62 at a first end and a second lug of a second terminal block 80 at a second end. The third AC bus bar 100 further includes a second conductor that is connected to the AC terminal of a sixth induction/PM power module 62 at a first end and to a third lug of the second terminal block at a second end.

The first and second AC bus bars 100 may be identical, or they may be slightly different to accommodate routing variations. Of course the bus bar routings described in the current disclosure serves as an example. A person of ordinary skill in the art would recognize that other bus bar routings are possible depending on the application, without departing from the spirit of the present disclosure. For instance, the same connectivity could be accomplished with three terminal blocks 80 with two lugs each.

Cable apertures 176 can be provide in the front, back, or bottom AC connection plates 170, 172, 174 to allow AC cables 190 to be connected to the terminal blocks 80 from the front, back, or bottom of the power converter package 10.

Though the AC Dual Topology 250 provides two power conversion stages, it may be useful in some applications to provide a DC connection box 120 so that an energy storage device (not shown) may be connected. The energy storage device could be a battery, ultracapacitor, or the like, or possibly to another power converter. The DC connection box 120 may be absent, or it may be located on the left or right side. In some applications it may be present on both the left and right sides.

Further, the AC Dual Topology 250 may have the coolant inlet/outlet connection 150, the controls connector 140, and the accessory connector 160 located on either of the left or right sides. The accessory connector 160 may be absent in some applications.

The third topology will be referred to as an “SR/AC Dual” topology. The SR/AC Dual Topology 260 is assembled from two power module sets 66. One power module set 66 contains three SR power modules while the other set contains three induction/PM power modules 62. The SR/AC Dual Topology 260 of the power converter package 10 provides two power conversion stages. That is, the SR/AC Dual Topology 260 receives AC power from an induction/PM (or SR) machine such as a generator, converts the power to DC, then converts the power to AC and provides AC power to an SR (or induction/PM) machine such as a motor. The SR/AC Dual Topology 260 could also receive DC power and drive an SR machine and an induction/PM machine.

The SR/AC Dual Topology 260 requires three different AC bus bars 100 of four, three, and two conductors. The SR/AC Dual Topology 260 uses terminal blocks 80 with three lugs. The SR/AC Dual Topology 260 uses an SR Dual Input/Four Terminal bus bar 101, a Hybrid SR/AC Three Terminal bus bar 103, and an AC Dual Input/Two Terminal bus bar 102.

For example, a first AC bus bar 100 includes a first conductor that is connected to the start terminal of a first SR power module 64 at a first end and a first lug of a first terminal block 80 at a second end. The first AC bus bar 100 further includes a second conductor that is connected to the finish terminal of the first SR power module 64 at a first end and to a second lug of the first terminal block at a second end. A third conductor is connected to the start terminal of a second SR power module 64 at a first end and a third lug of the first terminal block 80 at a second end. A fourth conductor is connected to the finish terminal of the second SR power module 64 at a first end and a first lug of a second terminal block 80 at a second end.

A second AC bus bar 100 includes a first conductor that is connected to the start terminal of a third SR power module 64 at a first end and a second lug of a second terminal block 80 at a second end. The second AC bus bar 100 further includes a second conductor that is connected to the finish terminal of the third SR power module 64 at a first end and to a third lug of the second terminal block at a second end. A third conductor is connected to the AC terminal of a fourth induction/PM power module 62 at one end and a first lug of a third terminal block 80 at a second end.

A third AC bus bar 100 includes a first conductor that is connected to the AC terminal of a fifth induction/PM power module 62 at one end and a second lug of a third terminal block 80 at a second end. The third AC bus bar 100 further includes a second conductor that is connected to the AC terminal of a sixth induction/PM power module 62 at one end and a third lug of a third terminal block 80 at a second end.

Of course the bus bar routings described in the current disclosure serves as an example. A person of ordinary skill in the art would recognize that other bus bar routings are possible depending on the application, without departing from the spirit of the present disclosure.

Cable apertures 176 can be provide in the front, back, or bottom AC connection plates 170, 172, 174 to allow AC cables 190 to be connected to the terminal blocks 80 from the front, back, or bottom of the power converter package 10.

Though the SR/AC Dual Topology 260 provides two power conversion stages, it may be useful in some applications to provide a DC connection box 120 so that an energy storage device (not shown) may be connected. The energy storage device could be a battery, ultracapacitor, or the like. The DC connection box 120 may be absent, or it may be located on the left or right side. In some applications it may be present on both the left and right sides.

Further, the SR/AC Dual Topology 260 may have the coolant inlet/outlet connection 150, the controls connector 140, and the accessory connector 160 located on either of the left or right sides. The accessory connector 160 may be absent in some applications.

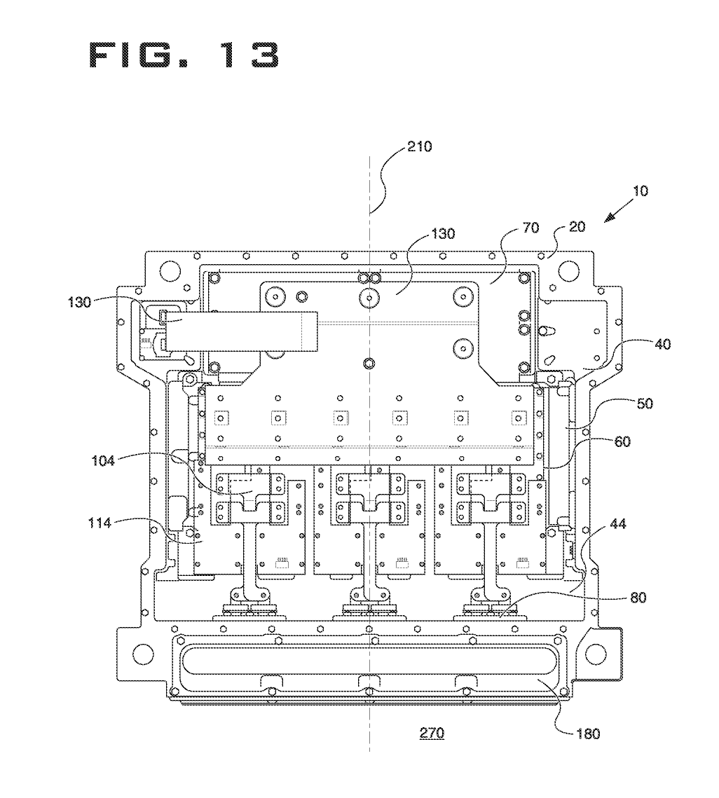

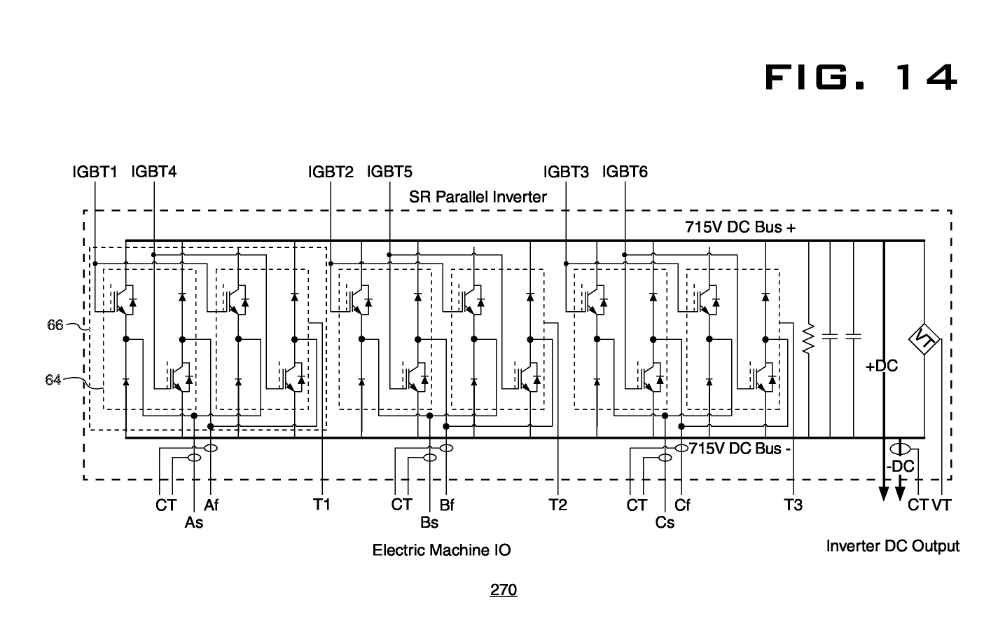

The fourth topology shown in FIG. 13 will be referred to as an SR Parallel Topology 270. The SR Parallel Topology 270 is assembled from two power module sets 66, with each set containing only SR power modules 64. The SR Parallel Topology 270 of the power converter package 10 provides a single power conversion stage. That is, the SR Parallel Topology 270 receives DC power from a DC source (such as the DC link of another power stage) then converts the power to AC and provides AC power to an SR machine such as a motor. Two SR power modules 64 are connected in parallel to increase current and power capacity. The fourth topology uses the parallel gate drive board 114. An example configuration of the SR Parallel Topology 270 is shown in FIG. 13. An equivalent circuit diagram of the SR Parallel Topology 270 is shown in FIG. 14.

Each AC bus bar 100 of the SR Parallel Topology 270 includes two conductors that connect the terminals of two SR power modules 64 to a lug on a terminal block 80. The SR Parallel Topology 270 uses terminal blocks 80 with two lugs. The AC bus bar 100 used in the SR Parallel Topology 270 will be referred to an SR Parallel Input/Two Terminal bus bar 104.

For example, a first AC bus bar 100 includes a first conductor that is connected to the start terminals of a first and second SR power module 64 at a first end and a first lug of a first terminal block 80 at a second end. The first AC bus bar 100 further includes a second conductor that is connected to the finish terminals of a first and second SR power module 64 at a first end and a second lug of a first terminal block 80 at a second end.

A second AC bus bar 100 includes a first conductor that is connected to the start terminals of a third and fourth SR power module 64 at a first end and a first lug of a second terminal block 80 at a second end. The second AC bus bar 100 further includes a second conductor that is connected to the finish terminals of a third and fourth SR power module 64 at a first end and a second lug of a second terminal block 80 at a second end.

A third AC bus bar 100 includes a first conductor that is connected to the start terminals of a fifth and sixth SR power module 64 at a first end and a first lug of a third terminal block 80 at a second end. The third AC bus bar 100 further includes a second conductor that is connected to the finish terminals of a fifth and sixth SR power module 64 at a first end and a second lug of a third terminal block 80 at a second end.

Cable apertures 176 can be provide in the front, back, or bottom AC connection plates 170, 172, 174 to allow AC cables 190 to be connected to the terminal blocks 80 from the front, back, or bottom of the power converter package 10.

The SR Parallel Topology 270 provides a single power conversion stage and includes a DC connection box 120 for connection to DC cables 192 that connect to another power stage or an energy storage device (not shown). The energy storage device could be a battery, ultracapacitor, or the like. The DC connection box 120 may be located on the left or right side. In some applications it may be present on both the left and right sides.

Further, the SR Parallel Topology 270 may have the coolant inlet/outlet connection 150, the controls connector 140, and the accessory connector 160 located on either of the left or right sides. The accessory connector 160 may be absent in some applications.

The fifth topology will be referred to as an SR Parallel/Parallel Output Topology 280. The SR Parallel/Parallel Output Topology 280 is assembled from two power module sets 66, with each set containing only SR power modules 64. The SR Parallel/Parallel Output Topology 280 of the power converter package 10 provides a single power conversion stage. That is, the SR Parallel/Parallel Output Topology 280 receives DC power from a DC source (such as the DC link of another power stage) then converts the power to AC and provides AC power to an SR machine such as a motor. Two SR power modules 64 are connected in parallel to increase current and power capacity. Parallel outputs are provided so that the AC cables 190 are required to carry less current. The fifth topology uses the parallel gate drive board 114.

Each AC bus bar 100 of the SR Parallel/Parallel Output Topology 280 includes two conductors that connect the terminals of two SR power modules 64 to two lugs on a terminal block 80. The SR Parallel/Parallel Output Topology 280 uses terminal blocks 80 with four lugs. The AC bus bar 100 used in the SR Parallel/Parallel Output Topology 280 will be referred to as an SR Parallel Input/Four Terminal bus bar 105.

For example, a first AC bus bar 100 includes a first conductor that is connected to the start terminals of a first and second SR power module 64 at a first end and a first and second lug of a first terminal block 80 at a second end. The first AC bus bar 100 further includes a second conductor that is connected to the finish terminals of a first and second SR power module 64 at a first end and a third and fourth lug of a first terminal block 80 at a second end.

A second AC bus bar 100 includes a first conductor that is connected to the start terminals of a third and fourth SR power module 64 at a first end and a first and second lug of a second terminal block 80 at a second end. The second AC bus bar 100 further includes a second conductor that is connected to the finish terminals of a third and fourth SR power module 64 at a first end and a third and fourth lug of a second terminal block 80 at a second end.

A third AC bus bar 100 includes a first conductor that is connected to the start terminals of a fifth and sixth SR power module 64 at a first end and a first and second lug of a third terminal block 80 at a second end. The first AC bus bar 100 further includes a second conductor that is connected to the finish terminals of a fifth and sixth SR power module 64 at a first end and a third and fourth lug of a third terminal block 80 at a second end.

Cable apertures 176 can be provide in the front, back, or bottom AC connection plates 170, 172, 174 to allow AC cables 190 to be connected to the terminal blocks 80 from the front, back, or bottom of the power converter package 10.

The SR Parallel/Parallel Output Topology 280 provides a single power conversion stage and includes a DC connection box 120 for connection to DC cables 192 that connect to another power stage or an energy storage device (not shown). The energy storage device could be a battery, ultracapacitor, or the like. The DC connection box 120 may be located on the left or right side. In some applications it may be present on both the left and right sides.

Further, the SR Parallel/Parallel Output Topology 280 may have the coolant inlet/outlet connection 150, the controls connector 140, and the accessory connector 160 located on either of the left or right sides. The accessory connector 160 may be absent in some applications.

The sixth topology will be referred to as an AC Parallel Topology 290. The AC Parallel Topology 290 is assembled from two power module sets 66, with each set containing only induction/PM power modules 62. The AC Parallel Topology 290 of the power converter package 10 provides a single power conversion stage. That is, the AC Parallel Topology 290 receives DC power from a DC source (such as the DC link of another power stage) then converts the power to AC and provides AC power to an induction/PM machine such as a motor. Two induction/PM power modules 62 are connected in parallel to increase current and power capacity. The sixth topology uses the parallel gate drive board 114.

Each AC bus bar 100 of the AC Parallel Topology 290 includes two conductors that connect the terminals of two induction/PM power modules 62 to a lug on a terminal block 80. The AC Parallel Topology 290 uses a terminal block 80 with three lugs. The AC bus bar 100 used in the AC Parallel Topology 290 will be referred to as an AC Parallel Input/One Terminal bus bar 106.

For example, a first AC bus bar 100 includes a conductor that is connected to the AC terminals of a first and second induction/PM power module 62 at a first end and a first lug of a first terminal block 80 at a second end.

A second AC bus bar 100 includes a conductor that is connected to the AC terminals of a third and fourth second induction/PM power module 62 at a first end and a second lug of a first terminal block 80 at a second end.

A third AC bus bar 100 includes a conductor that is connected to the AC terminals of a fifth and sixth induction/PM power module 62 at a first end and a third lug of a first terminal block 80 at a second end.

Cable apertures 176 can be provide in the front, back, or bottom AC connection plates 170, 172, 174 to allow AC cables 190 to be connected to the terminal blocks 80 from the front, back, or bottom of the power converter package 10.

The SR Parallel/Parallel Output Topology 280 provides a single power conversion stage and includes a DC connection box 120 for connection to DC cables 192 that connect to another power stage or an energy storage device (not shown). The energy storage device could be a battery, ultracapacitor, or the like. The DC connection box 120 may be located on the left or right side. In some applications it may be present on both the left and right sides.

Further, the SR Parallel/Parallel Output Topology 280 may have the coolant inlet/outlet connection 150, the controls connector 140, and the accessory connector 160 located on either of the left or right sides. The accessory connector 160 may be absent in some applications.

The seventh topology will be referred to as an ac parallel/parallel output topology 300. The AC Parallel/Parallel Out topology is assembled from two power module sets 66, with each set containing only induction/PM power modules 62. The AC Parallel/Parallel Out topology of the power converter package 10 provides a single power conversion stage. That is, the AC Parallel/Parallel Out topology receives DC power from a DC source (such as the DC link of another power stage) then converts the power to AC and provides AC power to an induction/PM machine such as a motor. Two induction/PM power modules 62 are connected in parallel to increase current and power capacity. The seventh topology uses the parallel gate drive board 114.

Each AC bus bar 100 of the ac parallel/parallel output topology 300 includes a conductor that connect the AC terminals of two induction/PM power modules 62 to a lug on a terminal block 80. The ac parallel/parallel output topology 300 uses terminal blocks 80 with two lugs. The AC bus bar 100 used in the AC Parallel/Parallel Output Topology 300 will be referred to as an AC Parallel Input/Two Terminal bus bar 107.

For example, a first AC bus bar 100 includes a conductor that is connected to the AC terminals of a first and second induction/PM power module 62 at a first end and a first and second lug of a first terminal block 80 at a second end.

A second AC bus bar 100 includes a conductor that is connected to the AC terminals of a third and fourth second induction/PM power module 62 at a first end and a first and second lug of a second terminal block 80 at a second end.

A third AC bus bar 100 includes a conductor that is connected to the AC terminals of a fifth and sixth induction/PM power module 62 at a first end and a first and second lug of a third terminal block 80 at a second end.

Cable apertures 176 can be provide in the front, back, or bottom AC connection plates 170, 172, 174 to allow AC cables 190 to be connected to the terminal blocks 80 from the front, back, or bottom of the power converter package 10.

The AC Parallel/Parallel Output Topology 300 provides a single power conversion stage and includes a DC connection box 120 for connection to DC cables 192 that connect to another power stage or an energy storage device (not shown). The energy storage device could be a battery, ultracapacitor, or the like. The DC connection box 120 may be located on the left or right side. In some applications it may be present on both the left and right sides.

Further, the AC Parallel/Parallel Output Topology 300 may have the coolant inlet/outlet connection 150, the controls connector 140, and the accessory connector 160 located on either of the left or right sides. The accessory connector 160 may be absent in some applications.

Of course the bus bar routings described in the current disclosure serves as an example. A person of ordinary skill in the art would recognize that other bus bar routings are possible depending on the application, without departing from the spirit of the present disclosure.

### INDUSTRIAL APPLICABILITY

The power converter package 10 of the current disclosure is designed to be adapted to a large number of configurations while changing a minimum number of components. The power converter package 10 is therefore configurable to fulfill the needs of an entire product line of electric drivetrains 310 for providing tractive effort on a machine 5. This saves NRE and tooling costs associated with creating new designs for every application. Further, using a single power converter package 10 across an entire product line increases volume which lowers the cost of the power converter package 10 by diluting the NRE and tooling costs over a larger volume. Since the power converters can be a significant portion of the cost of an electric drivetrain 310, this allows electric drivetrains 310 to be incorporated in more applications.

To this end, the housing 20, heat sink 50, filter caps 70, and DC bus bar 90 are common between every configuration. In addition, the power converter package 10 is designed to use one power module 60 footprint that supports both SR and induction/PM technology. This capability allows the power converter package 10 to connect to either an SR or induction/PM motor or generator while changing a minimum number of components.

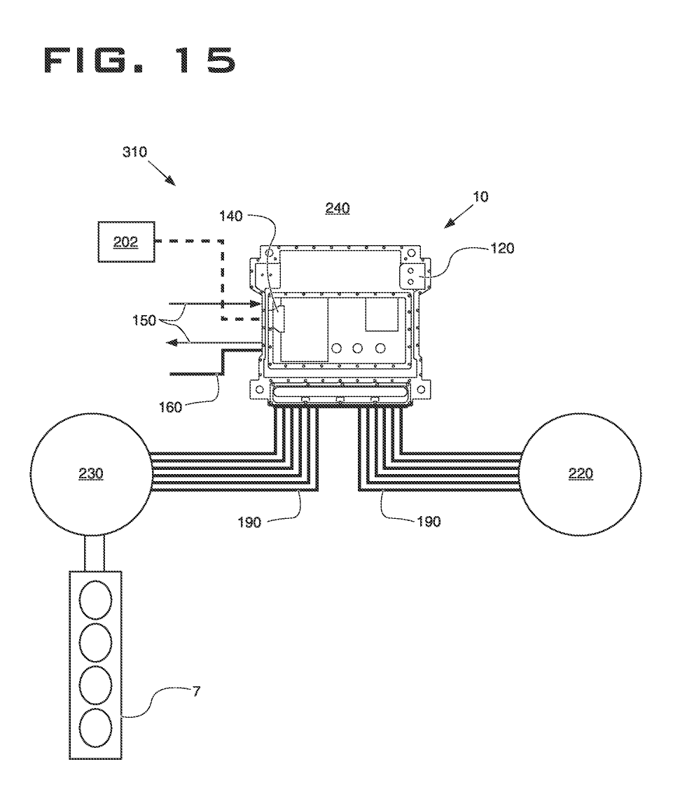

FIG. 15 shows one example of an electric drivetrain 310 according to the present disclosure. The power converter package 10 shown is an SR Dual Topology 240 and is connected to an SR generator 230 by a first set of six AC cables 190. The generator 230 is driven by a prime mover 7 such as an internal combustion engine. The AC cables 190 from the generator 230 are electrically connected to a first power module set 66 of SR power modules 64. An SR motor 220 is connected to the power converter package 10 by a second set of six AC cables 190. The AC cables 190 from the motor 220 are electrically connected to a second power module set 66 of SR power modules 64. The electric drivetrain 310 is configured such that, in normal operation, power flows from the generator 230, through the power converter package 10, and to the motor 220. The electric drivetrain 310 is configured such that power can also flow from the motor 220, through the power converter package 10, and to the generator 230. The SR Dual Topology 240 as shown in FIG. 15 is typically rated for around 650 V dc and 700 A rms.

The electric drivetrain 310 in FIG. 15 shows the controls connector 140, the coolant inlet/outlet connections 150, and the accessory connector 160 on one side of the power converter package 10. A DC connection box 120 may also be present. It should be understood that any of the preceding features could be located on either of the left or right sides in any combination as required by the application. Further, the AC cables 190 could be routed to either the front, back or rear of the power converter package 10.

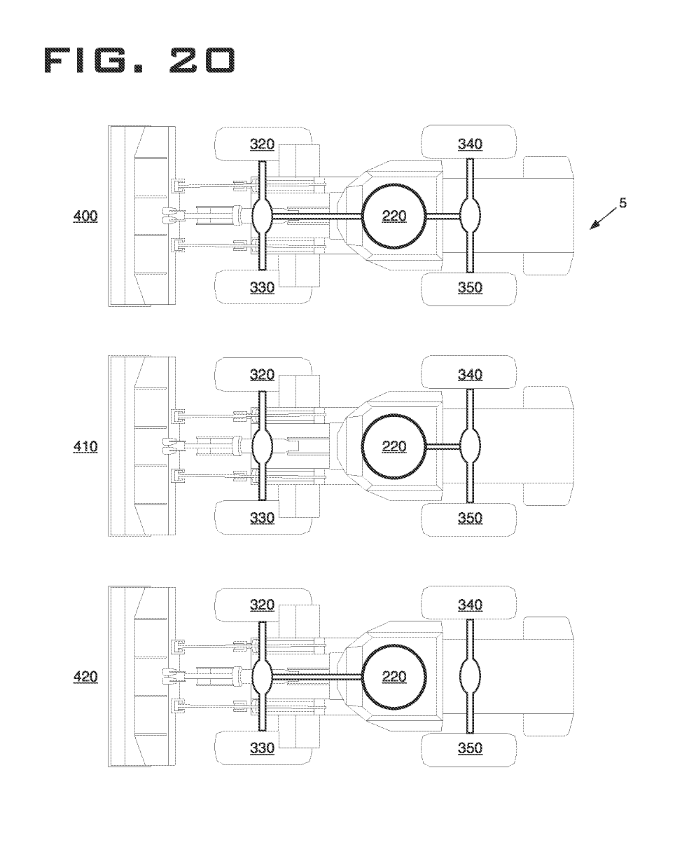

The motor 220 is drivingly connected to at least one wheel of the machine 5 via a driveshaft and final drive as is known in the art. In some applications, the motor 220 may be connected to more than one wheel, such as a right front wheel 320 and a left front wheel 330, or a right rear wheel 340 and a left rear wheel 350. In some applications, the motor 220 may be drivingly connected to all four wheels 320, 330, 340, and 350. FIG. 20 shows examples of one-motor drivetrain configurations 400, 410, and 420 that are contemplated by the current disclosure.

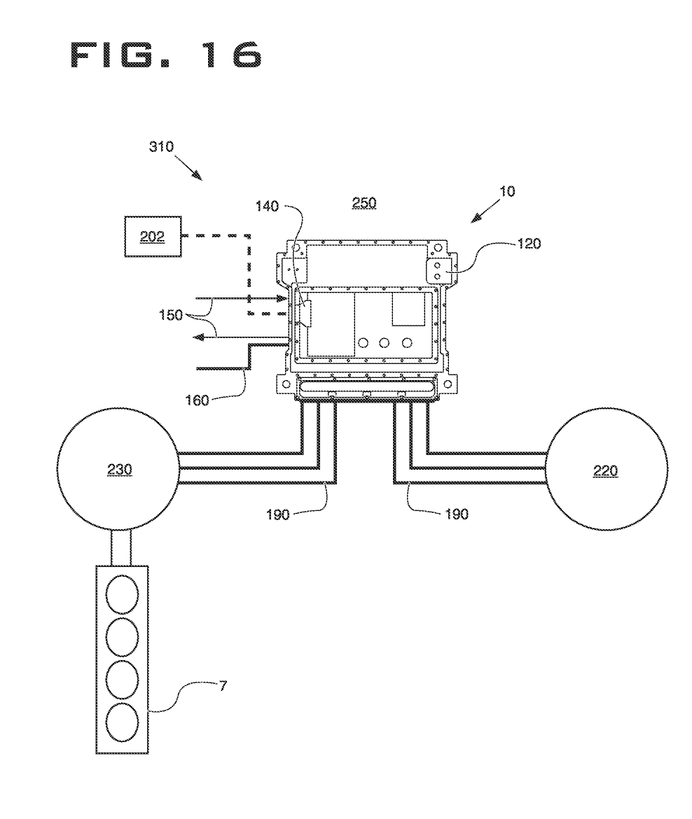

FIG. 16 shows another example of an electric drivetrain 310 according to the present disclosure. The power converter package 10 shown is an AC Dual Topology 250 and is connected to an induction/PM generator 230 by a first set of six AC cables 190. The generator 230 is driven by a prime mover 7 such as an internal combustion engine. The AC cables 190 from the generator 230 are electrically connected to a first power module set 66 of induction/PM power modules 62. An induction/PM motor 220 is connected to the power converter package 10 by a second set of six AC cables 190. The AC cables 190 from the motor 220 are electrically connected to a second power module set 66 of induction/PM power modules 62. The electric drivetrain 310 is configured such that, in normal operation, power flows from the generator 230, through the power converter package 10, and to the motor 220. The electric drivetrain 310 is configured such that power can also flow from the motor 220, through the power converter, and to the generator 230. The electric drivetrain 310 using an AC Dual Topology 250 as shown in FIG. 16 is typically rated for around 650 V dc and 700 A rms.

The electric drivetrain 310 in FIG. 16 shows the controls connector 140, the coolant inlet/outlet connections 150, and the accessory connector 160 on one side of the power converter package 10. A DC connection box 120 may also be present. It should be understood that any of the preceding features could be located on either of the left or right sides in any combination as required by the application. Further, the AC cables 190 could be routed to either the front, back or rear of the power converter package 10.

The motor 220 is drivingly connected to at least one wheel of the machine 5 via a driveshaft and final drive as is known in the art, as is shown in FIG. 20. In some applications, the motor 220 may be connected to more than one wheel, such as a right front wheel 320 and a left front wheel 330, or a right rear wheel 340 and a left rear wheel 350. In some applications, the motor 220 may be drivingly connected to all four wheels 320, 330, 340, and 350. FIG. 20 shows examples of one-motor drivetrain configurations 400, 410, and 420 that are contemplated by the current disclosure.

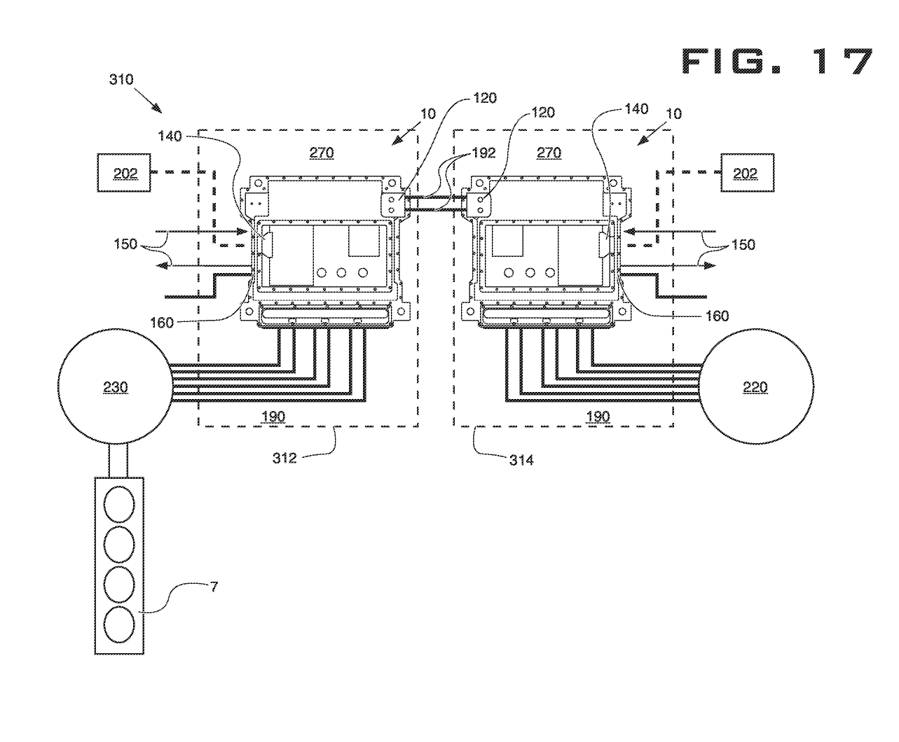

FIG. 17 shows another example of an electric drivetrain 310 according to the present disclosure. The power converter packages 10 shown are of the type SR Parallel Topology 270. The first power converter package 10 is connected to an SR generator 230 by a first set of six AC cables 190. The generator 230 is driven by a prime mover 7 such as an internal combustion engine. The AC cables 190 from the generator 230 are electrically connected to a first power module set 66 of six SR power modules 64 configured in parallel. An SR motor 220 is connected to a second power converter package 10 by a second set of six AC cables 190. The AC cables 190 from the motor 220 are electrically connected to a second power module set 66 of six SR power modules 64. The first and second power converter packages 10 are connected by DC cables 192. The electric drivetrain 310 is configured such that, in normal operation, power flows from the generator 230, through the first power converter package 10, to the second power converter package 10, and to the motor 220. The electric drivetrain 310 is configured such that power can also flow from the motor 220, through the second power converter package 10, through the first power converter package 10, and to the generator 230. The SR Parallel Topology 270 as shown in FIG. 17 is typically rated for around 650 V dc and 1400 A rms.

The electric drivetrain 310 in FIG. 17 shows the DC connection box 120, the controls connector 140, the coolant inlet/outlet connections 150, and the accessory connector 160 on one side of the power converter packages 10. It should be understood that any of the preceding features could be located on either of the left or right sides in any combination as required by the application. Further, the AC cables 190 could be routed to either the front, back or rear of the power converter package 10.

The motor 220 is drivingly connected to at least one driven member 360 of the machine 5. The driven member 360 could be an axle, driveshaft, wheel, drive sprocket, or final drive as is known in the art. In some applications, the motor 220 may be connected to more than one driven member 360, such as a right front wheel 320 and a left front wheel 330, or a right rear wheel 340 and a left rear wheel 350. In some applications, the motor 220 may be drivingly connected to all four wheels 320, 330, 340, and 350. FIG. 20 shows examples of one-motor drivetrain configurations 400, 410, and 420 that are contemplated by the current disclosure.

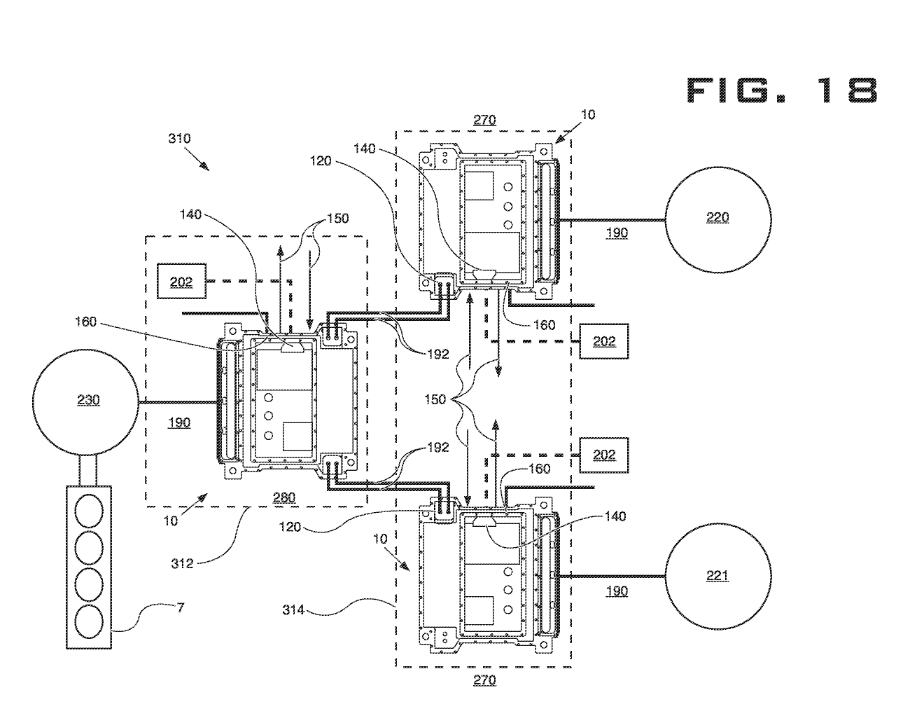

FIG. 18 shows another example of an electric drivetrain 310 according to the present disclosure. The electric drivetrain 310 comprises a first power conversion stage 312 and a second power conversion stage 314. The first power conversion stage 312 includes a power converter package 10 shown is of the type SR Parallel/Parallel Output Topology 280. The second power conversion stage 314 includes power converter packages 10 that are of the type SR Parallel Topology 270. The power converter package 10 in the first power conversion stage 312 is connected to an SR generator 230 by a first set of twelve AC cables 190. The generator 230 is driven by a prime mover 7 such as an internal combustion engine. The AC cables 190 from the generator 230 are electrically connected to a power module set 66 of six SR power modules 64. The power converter package 10 of the first power conversion stage 312 is configured with two DC connection boxes 120 and is connected to the power converter packages 10 of the second power conversion stage 314 by DC cables 192. SR motors 220, 221 are connected to each of the power converter packages 10 of the second power conversion stage 314 by sets of six AC cables 190. The AC cables 190 from the motors 220, 221 are electrically connected to a power module set 66 of six SR power modules 64 in each of the power converter packages 10 of the second power conversion stage 314. The electric drivetrain 310 is configured such that, in normal operation, power flows from the generator 230, through the first power conversion stage 312, to the second power conversion stage 314, and to the motors 220, 221. The electric drivetrain 310 is configured such that power can also flow in reverse from the motors 220, 221, through the second power conversion stage 314, through the first power conversion stage 312, and to the generator 230. The electric drivetrain 310 using SR Parallel/Parallel Output Topology 280 and SR Parallel Topology 270 as shown in FIG. 18 is typically rated for around 650 V dc and 1400 A rms.

The electric drivetrain 310 in FIG. 18 shows the DC connection box 120, the controls connector 140, the coolant inlet/outlet connections 150, and the accessory connector 160 on one side of the power converter package 10. It should be understood that any of the preceding features could be located on either of the left or right sides in any combination as required by the application. Further, the AC cables 190 could be routed to either the front, back or rear of the power converter package 10.

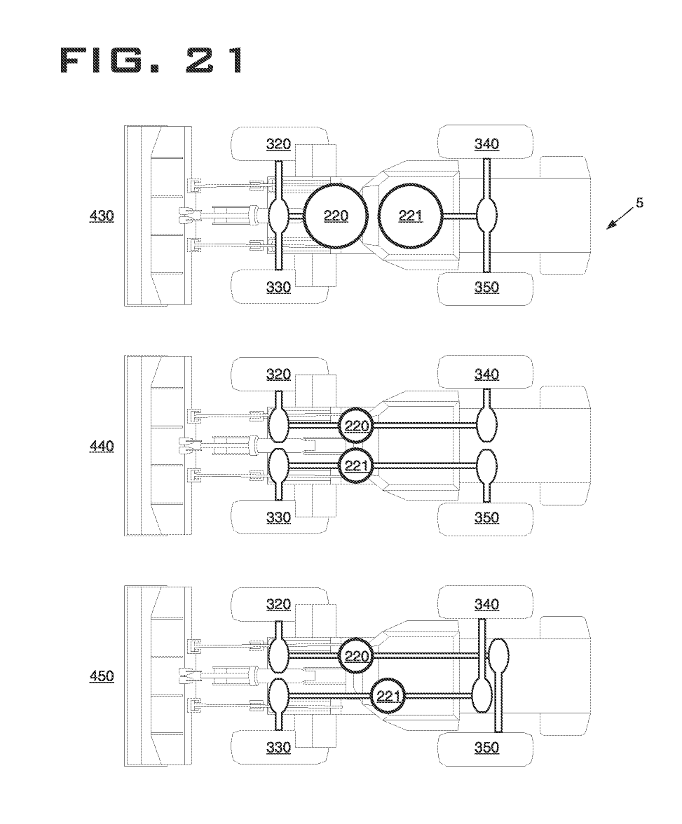

The motors 220, 221 are drivingly connected to at least one driven member 360 of the machine 5. The driven member 360 could be an axle, driveshaft, wheel, drive sprocket, or final drive as is known in the art. In some applications, the motors 220, 221 may be connected to more than one driven member 360, such as the motor 220 connected to a right front wheel 320 and a left front wheel 330, while a second motor 221 is connected to a right rear wheel 330 and a left rear wheel 340. The motor 220 may also be connected to a right front wheel 320 and right rear wheel 340, while a second motor 221 is connected to a left front wheel 330 and a left rear wheel 350 as is shown in. In still another example, the motor 220 may be connected to a right front wheel 320 and left rear wheel 350 while motor 221 is connected to left front wheel 330 and right rear wheel 340. FIG. 21 shows examples of two-motor drivetrain configurations 430, 440, and 450 that are contemplated by the current disclosure.

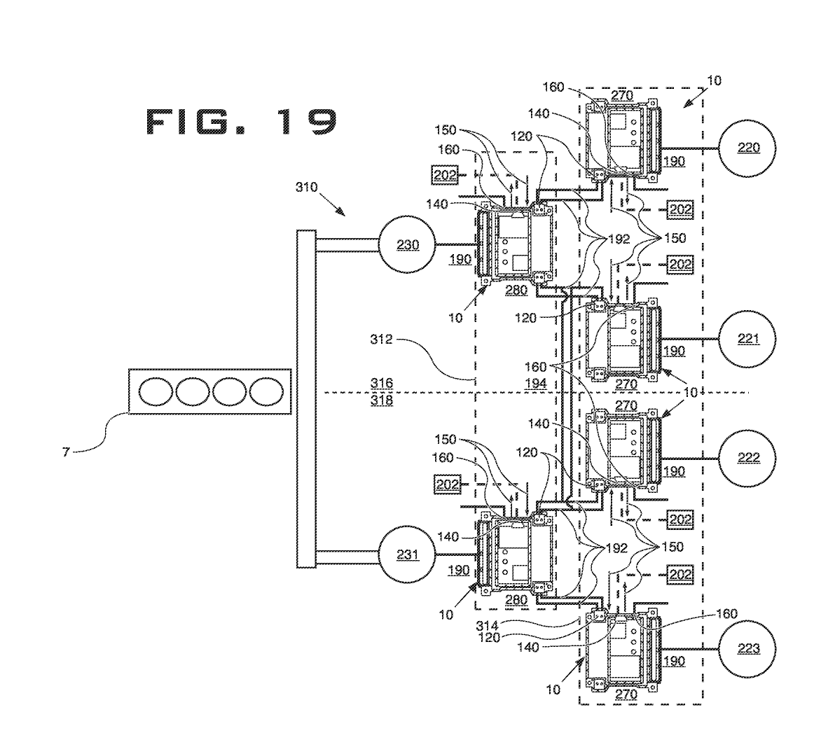

FIG. 19 shows another example of an electric drivetrain 310 according to the present disclosure. The electric drivetrain 310 comprises a first electric drivetrain portion 316 and a second drivetrain portion 318 and a first power conversion stage 312 and a second power conversion stage 314. The first power conversion stage 312 includes two power converter packages 10 of the type SR Parallel/Parallel Output Topology 280. The second power conversion stage 314 includes power converter packages 10 that are of the type SR Parallel Topology 270. The power converter packages 10 in the first power conversion stage 312 are connected to SR generators 230, 231 by sets of twelve AC cables 190. The generators 230 and 231 are driven by a prime mover 7 such as an internal combustion engine. The generators 230 and 231 may be driven by the same prime mover through a gear set or may be driven by individual prime movers 7.

The first electric drivetrain portion 316 and second electric drivetrain portion 318 each effectively forms a complete electric drive traction system, with full functionality for providing a first and second power conversion step. In addition, the power converter packages 10 of the first power conversion state 312 are connected by a DC bridge 194. The DC bridge 194 allows power to flow from first electric drivetrain portion 316 to the second electric drivetrain portion 318.

The AC cables 190 from the generators 230, 231 are electrically connected to a power module set 66 of six SR power modules 64 in each of the power converter packages 10 of the first power conversion stage 312. The power converter packages 10 of the first power conversion stage 312 are configured with two DC connection boxes 120 and are connected to the power converter packages 10 of the second power conversion stage 314 by DC cables 192. SR motors 220, 221, 222, and 223 are connected to the power converter packages 10 of the second power conversion stage 314 by sets of six AC cables 190. The AC cables 190 from the motors 220, 221, 222, and 223 are electrically connected to a power module set 66 of six SR power modules 64 in power converter packages 10 of the second power conversion stage 314. The electric drivetrain 310 is configured such that, in normal operation, power flows from the generator 230,231, through the first power conversion stage 312, to the second power conversion stage 314, and to the motors 220, 221, 222, and 223. The electric drivetrain 310 is configured such that power can also flow in reverse from the motors 220, through the second power conversion stage 314, through the first power conversion stage 312, and to the generators 230, 231. The electric drivetrain 310 using SR Parallel/Parallel Output Topology 280 and SR Parallel Topology 270 as shown in FIG. 19 is typically rated for around 650 V dc and 2800 A rms.

The electric drivetrain 310 in FIG. 19 shows the DC connection box 120, the controls connector 140, the coolant inlet/outlet connections 150, and the accessory connector 160 on one side of the power converter package 10. It should be understood that any of the preceding features could be located on either of the left or right sides in any combination as required by the application. Further, the AC cables 190 could be routed to either the front, back or rear of the power converter package 10.

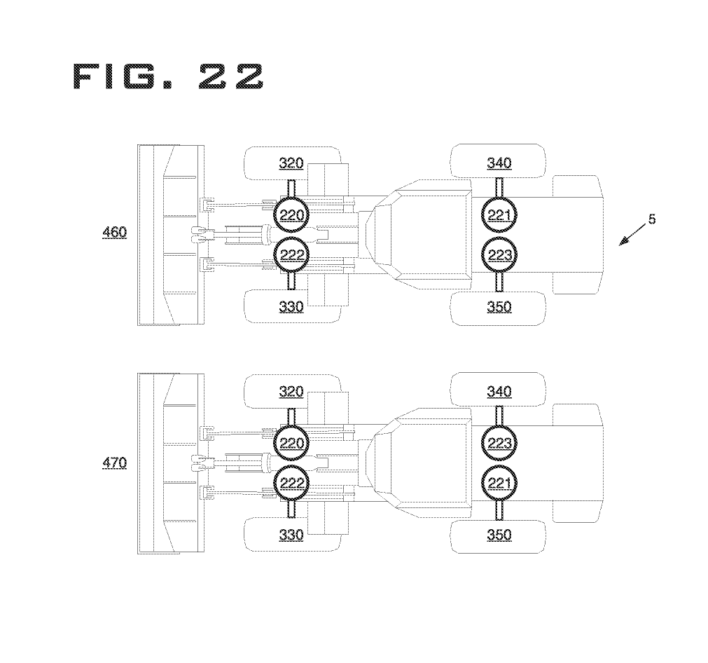

The motors 220, 221, 222, and 223 are drivingly connected to at least one driven member 360 of the machine 5. The driven member 360 could be an axle, driveshaft, wheel, drive sprocket, or final drive as is known in the art. In some applications, a motor 220 may be connected to more than one wheel. A single motor 220, 221, 222, or 223 may be connected to a single driven member 360 of the machine 5 as shown in FIG. 22. In one aspect of the current disclosure, two motors from a first electric drivetrain portion 316 are connected to driven members 360 on the right side of the machine 5 while two motors from a second electric drivetrain portion 318 are connected to driven members 360 on the left side of the machine 5. For instance, motor 220 is driveably connected to right front wheel 320, motor 221 is driveably connected to right rear wheel 340, motor 222 is driveably connected to left front wheel 330, and motor 223 is driveably connected to left rear wheel 350 as is shown in configuration 460 in FIG. 22. In another aspect of the current disclosure, two motors from a first electric drivetrain portion 316 are connected to driven members 360 on opposite sides of the machine 5 and two motors from a second electric drivetrain portion 318 are connected to driven members 360 on opposite sides of the machine 5. For instance, motor 220 is driveably connected to right front wheel 320, motor 221 is driveably connected to left rear wheel 350, motor 222 is driveably connected to left front wheel 330, and motor 223 is driveably connected to right rear wheel 340 as is shown configuration 470 in FIG. 22. The configuration 470 allows motors on the same sides (right/left) and ends (front/rear) of the machine 5 to be powered by different generators 230, 231. The “crisscross” pattern of the driven motors shown in configuration 470 may provide improved load distribution between the components (such as generators 230, 231) of the first electric drivetrain portion 316 and second electric drivetrain portion 318 depending on differing traction conditions between the sides (right/left) and ends (front/rear) of the machine 5. Configuration 470 may also provide improved load distribution between the components of the first electric drivetrain portion 316 and second electric drivetrain portion 318 on a machine that repeatedly performs the same turning motions. Therefore, configuration 470 may provide improved load distribution between components (such as generators 230, 231) of the first electric drivetrain portion 316 and second electric drivetrain portion 318 in an application such as a wheel loader performing a truck loading operation.

What is claimed is:

1. A power converter package comprising:
a housing configured to accept;
a heat sink;
a filter capacitor;
one of a plurality of terminal block configurations;
one of a plurality of configurations of power module configured in a set and mounted to said heat sink;
a DC bus bar electrically connected to said filter capacitor and said power modules;
one of a plurality of configurations of AC bus bars connected to said power module and said terminal block; and
wherein the power converter package forms one of a plurality of power configurations.

2. The power converter package of claim 1 wherein the power converter package forms one of a plurality of power configurations that is one of a dual and a parallel configuration.

3. The power converter package of claim 1 wherein the power converter package forms one of a plurality of power configurations as shown in FIG. 10.

4. The power converter package of claim 1 wherein the configuration of power module is one that supports one of SR and induction/PM technology.

5. The power converter package of claim 1 wherein one set of power modules is in a configuration that supports one of SR and induction/PM technology.

6. The power converter package of claim 1 wherein a first set of power modules is in a configuration that supports induction/PM technology and a second set is in a configuration that supports SR technology.

7. The power converter package of claim 1 further comprising one of a plurality of configurations of gate drive boards electrically connected to said power module.

8. The power converter package of claim 7 wherein the configuration of gate drive board is controllably attached to one of a single power module and two power modules.

9. The power converter package of claim 1 wherein the housing is configured to accept the heat sink mounted in one of two orientations.

10. The power converter package of claim 9 wherein the heat sink is mounted in an orientation that provides fluid connectivity on one of the left side and right side.

11. The power converter package of claim 1 wherein the housing is further configured to accept a DC connection box mounted in either of two locations.

12. The power converter package of claim 11 further comprising a DC access bus bar configured on a first end to connect to a plurality of positions on said DC bus bar and configured on a second end to connect to said DC connection box.

13. The power converter package of claim 1 wherein the configuration of AC bus bar is one of an SR Dual Input/Four Terminal bus bar, an AC Dual Input/Two Terminal bus bar, a Hybrid SR/AC Three Terminal bus bar, an SR Parallel Input/Two Terminal bus bar, an SR Parallel Input/Four Terminal bus bar, an AC Parallel Input/One Terminal bus bar, and an AC Parallel Input/Two Terminal bus bar.

14. A method for assembling a power converter package, comprising:
providing a housing;
mounting a heat sink;
mounting a filter capacitor to said housing;
mounting one of a plurality of terminal block configurations to said housing;
mounting one of a plurality of configurations of power module to said heat sink, said configurations configured in a set;
electrically connecting a DC bus bar to said filter capacitor and said power module;
electrically connecting one of a plurality of configurations of AC bus bars to said power module and said terminal block; and
wherein the power converter package forms one of a plurality of power configurations.

15. The method for assembling a power converter package of claim 14 wherein the power converter package forms one of a plurality of power configurations that is one of a dual and a parallel configuration.

16. The method for assembling a power converter package of claim 14 wherein the power converter package forms one of a plurality of power configurations as shown in FIG. 10.

17. The method for assembling a power converter package of claim 14 wherein the configuration of power module is one that supports one of SR and induction/PM technology.

18. The method for assembling a power converter package of claim 14 wherein one set of power modules is in a configuration that supports one of SR and induction/PM technology.

19. The method for assembling a power converter package of claim 14 wherein a first set of power modules is in a configuration that supports induction/PM technology and a second set is in a configuration that supports SR technology.

20. The method for assembling a power converter package of claim 14 further comprising one of a plurality of configurations of gate drive boards electrically connected to said power module.

21. The method for assembling a power converter package of claim 20 wherein the configuration of gate drive board is controllably attached to one of a single power module and two power modules.

22. The method for assembling a power converter package of claim 14 wherein the heat sink is mounted to said housing in one of two orientations.

23. The method for assembling a power converter package of claim 22 wherein the heat sink is mounted in an orientation that provides fluid connectivity on one of the left side and right side.

24. The method for assembling a power converter package of claim 14 wherein the housing is further configured to accept a DC connection box mounted in either of two positions.

25. The method for assembling a power converter package of claim 24 further comprising a DC access bus bar configured on a first end to connect to a plurality of positions on said DC bus bar and configured on a second end to connect to said DC connection box.

26. The method for assembling a power converter package of claim 14 wherein the configuration of AC bus bar is one of an SR Dual Input/Four Terminal bus bar, an AC Dual Input/Two Terminal bus bar, a Hybrid SR/AC Three Terminal bus bar, an SR Parallel Input/Two Terminal bus bar, an SR Parallel Input/Four Terminal bus bar, an AC Parallel Input/One Terminal bus bar, and an AC Parallel Input/Two Terminal bus bar.
